(19) United States
(12) Patent Application Publication
(10) Pub. No.: US 2023/0076844 A1
(43) Pub. Date: Mar. 9, 2023

(54) SEMICONDUCTOR DIE MODULE PACKAGES WITH VOID-DEFINED SECTIONS IN A METAL STRUCTURE(S) IN A PACKAGE SUBSTRATE TO REDUCE DIE-SUBSTRATE MECHANICAL STRESS, AND RELATED METHODS

(71) Applicant: QUALCOMM Incorporated, San Diego, CA (US)

(72) Inventors: Andreas Detlefsen, Eichenau (DE); Jeroen Bielen, Molenhoek (NL)

(21) Appl. No.: 17/470,961

(22) Filed: Sep. 9, 2021

(51) Int. Cl. H01L 23/00; H01L 23/498; H01L 21/48

(52) U.S. Cl. CPC H01L 23/562; H01L 23/49822; H01L 23/49866; H01L 23/49838; H01L 21/4857

(57) ABSTRACT

Semiconductor die module packages with void-defined sections in a metal structure(s) in a package substrate to reduce die-substrate mechanical stress, and related fabrication methods. To reduce die-substrate mechanical stress between the package substrate and a die(s) of the die module package, void-defined sections are formed in a metal structure(s) in a metallization layer(s) of the package substrate. The void-defined sections are formed from one or more cutouts of a metal material of the metal structure in a defined area to reduce stiffness, which also has the effect of reducing the effective coefficient of thermal. expansion (CTE) of the package substrate. The metal material remaining between the metal cutouts in a void-defined section form metal interconnects. Die interconnects can couple a die directly to the metal interconnects in the void-defined sections in the metal structure to reduce mechanical stress between the die and die interconnects to the package substrate.

### BACKGROUND

### Field of the Disclosure

The field of the disclosure relates to semiconductor die module packages, such as radio-frequency (RF) front end module packages, that can include various die components, like power amplifiers (PAs) and filters, and other integrated circuit (IC) chips, mounted on a package substrate.

### Background

Semiconductor devices are the cornerstone of electronic devices. Semiconductor devices are formed in a semiconductor die (“die”). One or more semiconductor dies can be packaged as subcomponents in a module package also called a “die module package.” One type of die module package is a radio-frequency (RF) die module package. A die module package includes one or more semiconductor dies either bare or in their own chip package, coupled to the package substrate. The package substrate provides a support structure for the dies. The package substrate includes one or more metallization layers that include metal interconnects (e.g., metal traces, metal lines, vertical interconnect accesses (vias)) for providing signal routing paths to the semiconductor dies. These signal routing paths can include external signal routing paths coupled to package interconnects external to the die module package as well as die-to-die (D2D) signal routing paths. Die interconnects (e.g., solder bumps) are provided to couple the dies to metal interconnects in an upper metallization layer of the package substrate to electrically couple the semiconductor dies to the metal interconnects in the package substrate for signal routing.

The different components of a die module package are fabricated from different materials that have different coefficients of thermal expansion (CTEs) that characterize their thermal expansion and contraction in response to temperature changes. For example, a package substrate being formed from a dielectric material and embedded metal (e.g., copper) traces may have a different CTE than the die interconnects used to electrically couple and mount a die to the package substrate. The package substrate may also have a different CTE than the subcomponent die or chip itself. Thus, when the die module package experiences changes in environmental temperature, the different materials of the die module package will experience mechanical stress forces due to thermal contraction and expansion. However, the different CTEs (i.e., CTE mismatch) of the different materials of the die module package will cause mechanical stress forces to be imparted repeatedly due to repeated thermal expansion and contraction. For example, these stress forces can particularly cause damage the die interconnects (bumps) coupling the die to the package substrate and/or the die itself, due to the difference in CTE between the die interconnects, the dies, and/or the package substrate. The die interconnects will eventually experience mechanical degradation known as “solder fatigue” due to repeated thermal stress. Further, if the die module package is a bare die module package where there is an air cavity present between a die mounted to the package substrate and the package substrate, the presence of the air cavity may not allow a stress-absorbing material to be disposed between the subcomponent die and the package substrate to mitigate the mechanical stress forces. For example, if the die module package includes an acoustic filter, an undermold material disposed underneath the filter between the acoustic filter and the substrate would interfere with the acoustic functions of the acoustic filter.

### SUMMARY OF THE DISCLOSURE

Aspects disclosed herein include semiconductor die module packages with void-defined sections in a metal structures) in a package substrate to reduce die-substrate mechanical stress. Related fabrication methods are also disclosed. The die module package includes one or more dies coupled to a package substrate for support and to provide electrical connectivity to the dies. For example, the semiconductor die (“die”) module package may be a radio-frequency (RF) die module package that includes one or more RF die subcomponents, such as an acoustic filter, mounted to a package substrate as one example. The package substrate includes at least one metallization layer that includes one or more metal structures to provide signal routing paths including ground planes for providing a ground potential connection between a die(s) mounted on the package substrate and electrically coupled to the metal structure. Die interconnects (e.g., solder bumps) electrically couple to the die(s) to metal structures in the package substrate. Mechanical stress forces can be imposed by the package substrate to the die interconnects, and in turn to the dies, due to changes in environmental temperature of the die module package, because the package substrate may have a different coefficient of thermal expansion (CTE) than the die interconnects and the dies. This can risk damage to the die interconnects and reliable electrical connections of the die to the package substrate. Thus, in exemplary aspects, to reduce die-substrate mechanical stress between the package substrate, the die interconnects, and the dies of the die module package, void-defined sections are formed in a metal structures) in a metallization layer(s) in the package substrate to reduce the stiffness of the metal structure within the void-defined sections. The void-defined sections are formed from one or more cutouts of a metal material of the metal structure in a defined area to reduce stiffness, which also has the effect of reducing the effective CTE of the package substrate. The metal material remaining between the metal cutouts in a void-defined section form metal interconnects. Metal structures that include void-defined sections can be provided in one, multiple, and/or all metallization layers of the package substrate. For example, a plurality of metal structures can be provided in multiple metallization layers that are parallel to each other such that the metal structures are also parallel to each other in a horizontal direction and sharing a common vertical plane to at least partially overlapping each other in a vertical direction in the package substrate to reduce the stiffness of the package substrate. The die(s) in the die module package can be oriented on the package substrate such that the die is located above and the void-defined sections located below the die(s). The die interconnects couple the dies (directly or indirectly through metal interconnects in intervening metallization layers) to metal interconnects in the void-defined sections of reduced stiffness in the metal structures to buffer and thus reduce mechanical stress between the coupling of the die and die interconnects to the package substrate.

In other exemplary aspects, the cutouts in the metal structures that define the void-defined sections in the metal structures can be further optionally filled with material that has a lower CTE than the CTE of the metal material of the ground plane(s) to further reduce the stiffness of the void-defined sections and effective CTE of the package substrate. Further reducing the stiffness and effective CTE of the void-defined section where connections are made to the die interconnects and die can further reduce mechanical stress between the package substrate and the die interconnects and/or the dies.

In one exemplary aspect, patterned voids can be disposed in a metal structure of the package substrate to be uniform in all axes of direction to provide flexibility equally in all axes of direction. In another exemplary aspect, the patterned voids in the metal structure(s) of the package substrate can be biased to be elongated in certain axes of direction to provide enhanced flexibility in certain axes of direction. In another exemplary aspect, the patterned voids in the metal structure(s) of the package substrate can be designed such that vertical interconnect accesses (vias) extend through one or more of the voids to support vias extending through and connected to the metal structure(s). In another exemplary aspect, the voids in the metal structures) of the package substrate can be patterned to be selectively provided adjacent to metal traces and/or other electrical components in the package substrate to provide selective mechanical stress relief to such metal traces and/or other electrical components.

In this regard, in one exemplary aspect, a die module package substrate is provided. The die module package includes a package substrate. The package substrate includes a plurality of metal structures parallel to each other in a horizontal direction and sharing a common vertical plane. Each metal structure among the plurality of metal structures includes a metal material having a first CTE. Each metal structure among the plurality of metal structures also includes a void-defined section including a plurality of voids disposed in the metal structure. Each metal structure among the plurality of metal structures also includes one or more metal interconnects each formed by the metal material in the metal structure disposed between adjacent voids among the plurality of voids. Each metal structure among the plurality of metal structures also includes a dielectric material having a second CTE disposed in at least one void among the plurality of voids in the void-defined section. The second CTE of the dielectric material is less than the first CTE of the metal material. The die module package also includes a die disposed adjacent to the package substrate. The die module package also includes at least one die interconnect each coupled to the die and each coupled to a metal interconnect among the one or more metal interconnects in the void-defined section of at least one metal structure among the plurality of metal structures.

In another exemplary aspect, a method of fabricating a die module package is provided. The method includes forming a package substrate. Forming the package substrate includes forming a plurality of metal structures parallel to each other in a horizontal direction and sharing a common vertical plane. Each metal structure among the plurality of metal structures comprises a metal material having a first CTE, a void-defined section comprising a plurality of voids disposed in the metal structure, one or more metal interconnects each formed by the metal material in the metal structure disposed between adjacent voids among the plurality of voids, and a dielectric material having a second CTE disposed in at least one void among the plurality of voids in the void-defined section, the second CTE of the dielectric material less than the first CTE of the metal material. The method also includes forming at least one die interconnect coupled to at least one metal interconnect among the one or more metal interconnects in the void-defined section of at least one metal structure among the plurality of metal structures. The method also includes coupling a die to the at least one die interconnect.

### BRIEF DESCRIPTION OF THE FIGURES

FIG. 1 is a side view of an exemplary semiconductor die (“die”) module package with die interconnects coupling dies to void-defined sections in metal structures, wherein the void-defined sections are formed by voids in a metal material of the metal structure(s), to reduce metal stiffness of the metal structure(s) to reduce die-substrate mechanical stress between the package substrate and the die interconnects and dies;

FIG. 2 is a top view of an exemplary substrate layer in a package substrate, such as the package substrate in FIG. 1, wherein the substrate layer includes ground planes having void-defined sections configured to be coupled to die interconnects coupled to a die, to reduce die-substrate mechanical stress between the package substrate and the die interconnects and dies;

FIG. 3 is a top view of an exemplary metal structure in a metallization layer in a package substrate with patterned voids providing void-defined sections in the ground plane to reduce stiffness in the void-defined sections of the ground plane and to reduce the overall coefficient of thermal expansion (CTE) of the ground plane;

FIG. 4A is a graph illustrating exemplary simulated results of the CTE of the metal structure in FIG. 3;

FIG. 4B is a graph illustrating the exemplary simulated results of the CTE of a metal structure like in FIG. 3, but without the patterned voids;

FIG. 5 is a graph illustrating the effective CTE of the metal structure in FIG. 3 as a function of the volume of various metal materials used to form the metal structure;

FIG. 6 is a top view of another exemplary ground plane with patterned voids biased in an axis of direction to reduce metal stiffness of the metal structure perpendicularly biased in the axis of direction;

FIG. 7 is a top view of another exemplary ground plane with patterned voids forming void-defined sections in the metal structure to reduce stiffness in the void-defined sections, wherein vertical interconnect accesses (vias) are selectively disposed in voids;

FIG. 8 is a top view of another exemplary metal structure with elongated patterned voids biased in an axis of direction and forming void-defined sections in the metal structure to reduce stiffness of the ground plane biased perpendicular to the axis of direction;

FIGS. 9A-9H are top views of other exemplary metal structures with voids selectively provided adjacent to metal traces and/or other electrical components in a package substrate to form void-defined sections in the metal structures providing selective mechanical stress relief to such metal traces and/or other electrical components;

FIG. 10 is a flowchart illustrating an exemplary fabrication process of fabricating a die module package that includes a package substrate that includes one or more metal structures with void-defined sections formed by voids in a metal material of the metal structure(s) to reduce metal stiffness of the metal structures) to reduce die-substrate mechanical stress between the package substrate and the die interconnects and dies;

FIG. 11 is a block diagram of an exemplary wireless communications device that includes radio-frequency (RF) components that can be provided in respective die module packages that include a package substrate that includes one or more metal structures with void-defined sections formed by voids in a metal material of the metal structure(s) to reduce metal stiffness of the metal structure(s), including, but not limited to, the package substrates in FIGS. 1-3 and 6-9H, and according to the exemplary fabrication process in FIG. 10; and

FIG. 12 is a block diagram of an exemplary processor-based system that can be provided in respective die module packages that include a package substrate that includes one or more metal structures with void-defined sections formed by voids in a metal material of the metal structure(s) to reduce metal stiffness of the metal structure(s), including, but not limited to, the package substrates in FIGS. 1-3 and 6-9H, and according to the exemplary fabrication process in FIG. 10.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include semiconductor die module packages with void-defined sections in a metal structure(s) in a package substrate to reduce die-substrate mechanical stress. Related fabrication methods are also disclosed. The die module package includes one or more dies coupled to a package substrate for support and to provide electrical connectivity to the dies. For example, the semiconductor die (“die”) module package may be a radio-frequency (RF) die module package that includes one or more RF die subcomponents, such as an acoustic filter, mounted to a package substrate as one example. The package substrate includes at least one metallization layer that includes one or more metal structures to provide signal routing paths including ground planes for providing a ground potential connection between a die(s) mounted on the package substrate and electrically coupled to the metal structure. Die interconnects (e.g., solder bumps) electrically couple to the die(s) to metal structures in the package substrate. Mechanical stress forces can be imposed by the package substrate to the die interconnects, and in turn to the dies, due to changes in environmental temperature of the die module package, because the package substrate may have a different coefficient of thermal expansion (CTE) than the die interconnects and the dies. This can risk damage to the die interconnects and reliable electrical connections of the die to the package substrate. Thus, in exemplary aspects, to reduce die-substrate mechanical stress between the package substrate, the die interconnects, and/or the dies of the die module package, void-defined sections are formed in a metal structure(s) in a metallization layer(s) in the package substrate to reduce the stiffness of the metal structure within the void-defined sections. The void-defined sections are formed from one or more cutouts of a metal material of the metal structure in a defined area to reduce stiffness, which also has the effect of reducing the effective CTE of the package substrate. The metal material remaining between the metal cutouts in a void-defined section form metal interconnects. Metal structures that include the void-defined section can be provided in one, multiple, and/or all metallization layers of the package substrate. For example, a plurality of metal structures can be provided in multiple metallization layers that are parallel to each other such that the metal structures are also parallel to each other in a horizontal direction and sharing a common vertical plane to at least partially overlapping each other in a vertical direction in the package substrate to reduce the stiffness of the package substrate. The die(s) in the die module package can be oriented on the package substrate such that the die is located above and the void-defined sections located below the die(s). The die interconnects couple the dies (directly or indirectly through metal interconnects in intervening metallization layers) to metal interconnects in the void-defined sections of reduced stiffness in the metal structures to buffer and thus reduce mechanical stress between the coupling of the die and die interconnects to the package substrate.

In other exemplary aspects, the cutouts in the metal structures that define the void-defined sections in the metal structures can be further optionally filled with material that has a lower CTE than the CTE of the metal material of the ground plane(s) to further reduce the stiffness of the void-defined sections and effective CTE of the package substrate. Further reducing the stiffness and effective CTE of the void-defined section where connections are made to the die interconnects and die can further reduce mechanical stress between the package substrate and the die interconnects and/or the dies.

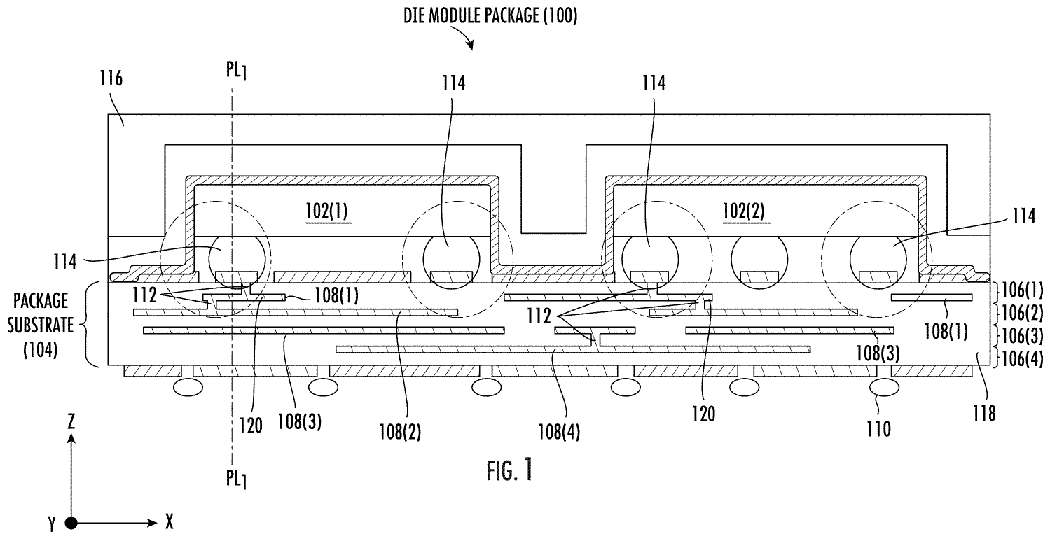

In this regard, FIG. 1 is a side view of an exemplary semiconductor die (“die”) module package 100 that includes two semiconductor dies (“dies”) 102(1), 102(2) adjacent to and coupled to a package substrate 104. For example, the die module package 100 may be a RF die module package where the dies 102(1), 102(2) are RF components, such as an acoustic filter or RF amplifier. The package substrate 104 could be a coreless or cored substrate. The package substrate 104 includes metallization layers 106(1)-106(4) that each include metal structures 108(1)-108(4) for providing signal routing paths between the dies 102(1), 102(2) and external interconnect bumps 110 of the die module package 100. For example, the metal structures 108(1)-108(4) may be formed from redistribution of the metal material or formed in a laminated metallization layer 106(1)-106(4) in a laminating process. The metal structures 108(1)-108(4) provide metal interconnects (e.g., metal lines, metal traces). The metal structures 108(1)-108(4) can also serve as a ground plane for the dies 102(1), 102(2). The metal structures 108(1)-108(4) can provide die-to-die interconnects (D2D) between the dies 102(1), 102(2). Vertical interconnect accesses (vias) 112 are coupled between metal structures 108(1)-108(4) in respective metallization layers 106(1)-106(4) in the package substrate 104 to provide signal routing between different metallization layers 106(1)-106(4). Die interconnects 114 (e.g., solder bumps) are coupled to the die(s) 102(1), 102(2) and the metal structures 108(1) in the upper metallization layer 106(1) in the package substrate 104 to electrically couple the dies 102(1), 102(2) to the package substrate 104. The die interconnects 114 can also indirectly be coupled to other metal structures 108(2)-108(4) in underlying metallization layers 106(2)-106(4) due to interconnectivity between such metal structures 108(2)-108(4) through the vias 112. Some metal structures 108(1)-108(4) may serve as a ground plane for ground potential couplings to the dies 102(1), 102(4) through the die interconnects 114. The dies 102(1), 102(2) are encapsulated by an overmold material 116 on the package substrate 104.

Mechanical stress forces can be imposed by the package substrate 104 to the die interconnects 114, and in turn to the dies 102(1), 102(2), due to changes in environmental temperature of the die module package 100. This is because the package substrate 104 may have a different CTE than the die interconnects 114 and/or the dies 102(1), 102(2). This can risk damage to the die interconnects 114 and reliable electrical connections of the dies 102(1), 102(2) to the package substrate 104. The polymer material 118 of the package substrate 104 is generally a softer material that has a lower CTE as compared to a metal material used to form the metal structures 108(1)-108(4) in the package substrate 104 and the die interconnects 114. When mechanical forces are imparted on the package substrate 104, these mechanical forces can be transferred to the metal structures 108(1)-108(4) of the package substrate 104, which are in turn transferred to the die interconnects 114 and the dies 102(1), 102(2). If these forces are too great, the connectivity between the dies 102(1), 102(2) and the metal structures 108(1)-108(4) can be damaged, thus degrading the electrical connectivity of the die module package 100. For example, these mechanical forces can be due to changes in environmental temperature experienced by the die module package 100. Due to differences in CTE, the dies 102(1), 102(2), the die interconnects 114, and the metal structures 108(1)-108(4) in the package substrate 104 may thermally contract and expand differently, in different amounts and distances, such as in the X-, Y-, and Z-axis directions in FIG. 1, based on a given change in temperature. These stress forces can particularly cause damage in the corners of the dies 102(1), 102(2) and/or the die interconnects 114. While the polymer material 118 of the package substrate 104 can buffer some of the mechanical stresses imparted to the package substrate 102, repeated mechanical stresses through repeated thermal expansion and contraction may still be significant over time to damage the electrical connections between the dies 102(1), 102(2) and the package substrate 104.

Thus, in exemplary aspects, to reduce die-substrate mechanical stress between the package substrate 104, the die interconnects 114, and/or the dies 102(1), 102(2) of the die module package, void-defined sections 120 are formed in metal structures 108(1) in this example, as shown in FIG. 1. This reduces the stiffness of areas of these metal structures 108(1) where the die interconnects 114 are coupled to in turn reduce mechanical stress transfer from the package substrate 104 to the die interconnects 114 and the dies 102(1), 102(2). As will be discussed in more detail below, the void-defined sections 120 are formed from one or more cutouts of a metal material of the metal structure 108(1) in a defined area to reduce stiffness, which also has the effect of reducing the effective CTE of the package substrate 104. The overall effective CTE of the package substrate 104 is less than the CTE of the metal material of the metal structures 108(1)-108(4) in this example. The metal material remaining between the metal cutouts in a void-defined section 120 form metal interconnects. The void-defined sections 120 can be provided in certain metal structures 108(1)-108(4) in one, multiple, and/or all metallization layers 106(1)-106(4) of the package substrate 104. The die(s) 102(1), 102(2) in the die module package 100 can be oriented on the package substrate 104 such that the dies 102(1), 102(2) are located above and void-defined sections 120 in the metal structure 108(1) located below the die(s) 102(1), 102(2). This allows the die interconnects 114 to couple the dies 102(1), 102(2) (directly or indirectly through metal structures 108(2)-108(4) in intervening metallization layers 106(2)-106(4)) to metal interconnects in the metal structure 108(1) in the void-defined sections 120 of reduced stiffness to buffer and thus reduce mechanical stress between the coupling of the dies 102(1), 102(2) and die interconnects 114 to the package substrate 104.

Note that if it is desired to further reduce stiffness of the package substrate 104, one or more of the additional metal structures 108(2)-108(4) can also be provided that include void sections that are formed from one or more cutouts of a metal material of the respective metal structure 108(2)-108(4). For example, such metal structures 108(2)-108(4) can be aligned to be parallel to each other in a horizontal direction (e.g., in an X-axis direction) and share a common vertical plane PL₁ (in the Z- and Y-axis directions) in FIG. 1 to be at least partially overlapping each other in the vertical direction (Z-axis direction). Thus, die interconnects 114 that couple a die to metal interconnects in the metal structure 108(1) will benefit from reduced stiffness and stress forces from the package substrate 104 from the other metal structures 108(2)-108(4) beneath the metal structure 108(1). For example, these other metal structures 108(2)-108(4) may allow the metal structure 108(1) to more easily bend thus reducing stress forces on the die interconnects 114 and the dies 102(1), 102(2).

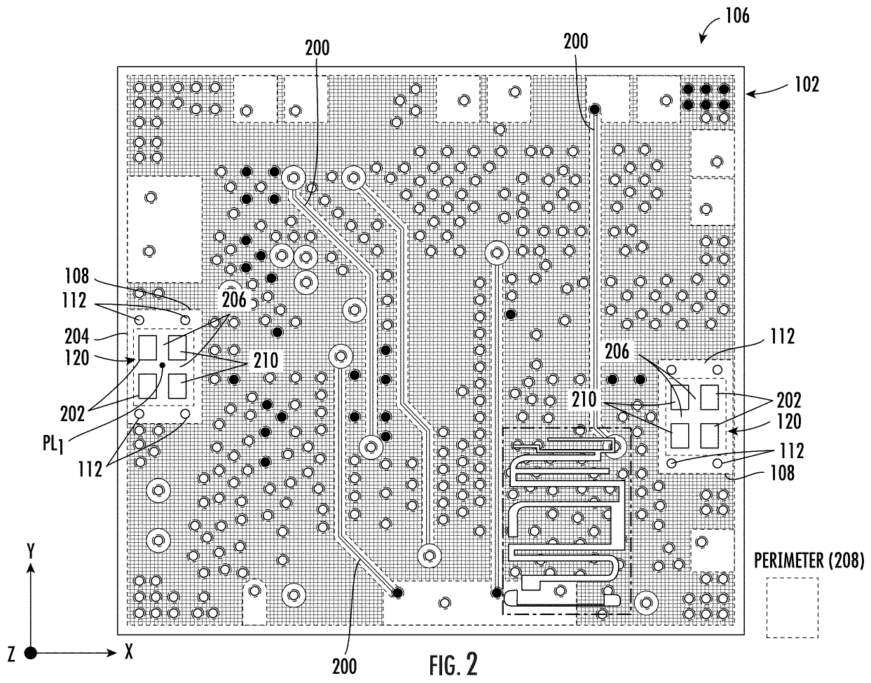

FIG. 2 is a top view of an exemplary metallization layer 106 that can be provided in the package substrate 104 in the die module package 100 in FIG. 1 as an example. As shown in FIG. 2, the metallization layer 106 includes metal structures 108 (e.g., metal planes), which can include metal structures acting as a ground plane. Note that the metal structures 108 could be provided as any of the metal structures 108(1)-108(4) in the package substrate 104 in FIG. 1. The metallization layer 106 also includes metal traces 200 that are not planar structures like the metal structures 108. The metallization layer 106 in FIG. 2 may be the upper metallization layer 106(1) in the package substrate 104 in FIG. 1 that is directly coupled to and adjacent to the die interconnects 114 in the die module package 100. For example, if a metal structure 108 in the metallization layer 106 in FIG. 2 serves as a ground plane, such metal structure 108 acting as a ground plane can be located directly underneath die interconnects 114 for electrical connectivity of a ground potential to the dies 102(1), 102(2). As shown in FIG. 2, the metal structures 108 in this example each include voids 202 disposed in a pattern to form void-defined sections 120. In this example, the voids 202 are cut-out sections of the metal material 204 in the metal structures 108. By “patterned” voids, it is meant that the voids 202 are disposed in the metal structure 108 in an intended location and design such that the voids 202 are not randomly disposed in the metal structure 108. In this example, the voids 202 form a perimeter 208 of the void-defined sections 120 in the metal structures 108.

The metal material 204 remaining between adjacent voids 202 in the metal structure 108 forms metal interconnects 206 (e.g., metal lines, traces) that can be coupled to a die interconnect 114 (directly or indirectly) or via 112 to electrically couple to the metal structure 108. In this manner, the voids 202 disposed in the void-defined section 120 of a metal structure 108 reduce the stiffness of the metal structure 108 in an area where electrical connections to the metal interconnects 206 can be made to reduce the stress forces imparted from the metal structure 108 to such connections. However, the metal structures 108 still retain their metal material structure and provide metal interconnects 206 for connectivity. For example, the area of the voids 202 in a given void-defined section 120 may be at least eight five percent (85%) of the area of its perimeter 208 in the metal structure 108.

With references to FIGS. 1 and 2, note that portion of a die 102(1), 102(2) can be oriented to the package substrate 104 to at least partially overlap a void-defined section 120 in a metal structure 108 in the package substrate 104 in a vertical direction, which is the Z-axis direction in this example. This allows the die interconnects 114 to more easily couple a die 102(1), 102(2) to a metal interconnect(s) 206 in a void-defined section 120 of a metal structure 108 to provide electrical connectivity. Also note that although vias 112 are shown apart and separate from the voids 202 in the metal structures 108 in the metallization layer 106 in FIG. 2, some voids 202 could be filled in with a metal material to form a via 112 that extends through the void 202. Also, as will also be discussed in more detail below, the voids 202 may be shaped and disposed in a metal structure 108 defining a void-defined section 120 in the metal structure 108 to achieve a uniform reduction in stiffness imparted in all directions, or biased in X- and Y-axis directions in a void-defined section 120. Alternatively, the voids 202 may be shaped and disposed in a metal structure 108 defining a void-defined section 120 in the metal structure 108 to achieve a biased or non-uniform reduction in stiffness imparted in no particular direction or only in certain directions.

In this example, the voids 202 in the metal structures 108 can also be optionally filled with a dielectric material 210, such as a polymer or laminate material, to further reduce the stiffness of the metal structure 108. The dielectric material 210 can be chosen to have a lower CTE than the CTE of the metal material 204 forming the metal structure 108. For example, the CTE of the metal material 204 forming the metal structures 108 may be between 13 parts per million (ppm) per Kelvin (ppm/K) and 24 ppm/K. The metal material 204 may be Aluminum Nickel (AlNi) or an alloy thereof for example. As another example, if the metal material 204 forming the metal structures 108 is copper for example, the CTE of the metal material 204 of the metal structures 108 may be 18_ppm/K as another example. The CTE of the dielectric material 210 disposed in the voids 202 of the metal structures 108 may be between 4_ppm/K and 18 ppm/K. as an example. If the dielectric material 210 filled in the voids 202 is a low CTE glass fiber polymer for example, the CTE of the dielectric material 210 may be approximately 6_ppm/K as another example. Examples of fiber for reinforcement of the dielectric material 210 include carbon fiber and aluminum oxide (Al₂O₃) spheres. As another example, the voids 202 may be disposed in a metal structure 108 such that the Young's modulus (i.e., stiffness) of the voids 202 in the void-defined section 120 in the metal structure 108 may be between 100 MegaPascal (MPa) and 50 GigaPascal (GPa). Note that although FIG. 2 only shows a view of one metallization layer 106 of the package substrate 104 in FIG. 1, void-defined sections 120 can be formed in any metal structures 108(1)-108(4) in any metallization layer 106(1)-106(4) of the package substrate 104. For example, if a die interconnect 114 is coupled to multiple metal structures 108(1)-108(4) in multiple metallization layers 106(1)-106(4) through direct connect to a metal structure 108(1) in an upper metallization layer 106(1) and through via 112 connections to other metallization layers 106(2)-106(4), the subsequent connections of such vias 112 in such other metallization layers 106(2)-106(4) can be void-defined sections 120 in such metal structures 108(2)-108(4) in such other metallization layers 106(2)-106(4). This can further reduce the stress imparted by the package substrate 104 to the die interconnects 114 and in turn their coupled dies 102(1), 102(2). And as discussed above, one or more of the metal structures 108(1)-108(4) with void sections 120 can be aligned to be parallel to each other in a horizontal direction (e.g. in an X-axis direction) and sharing a common vertical plane PL₁ (in the Z- and Y-axis directions) in the package substrate 104 to be at least partially overlapping each other in the vertical direction (Z-axis direction) to support reduced stiffness.

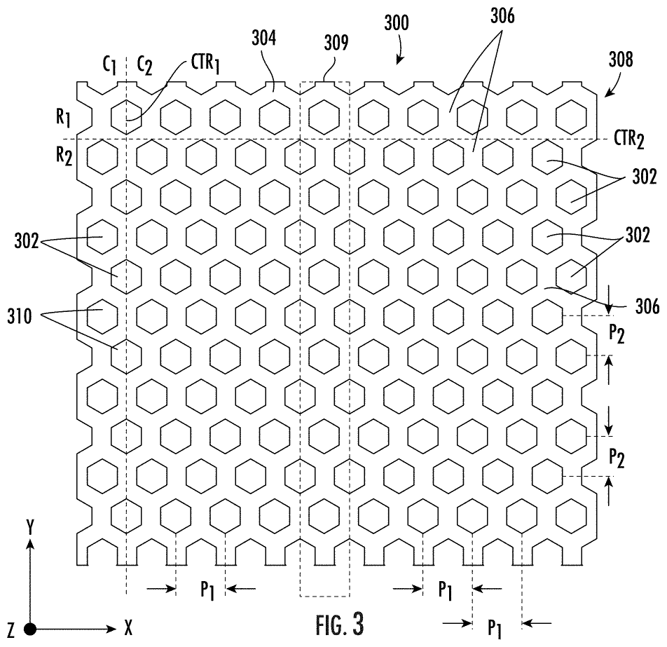

The voids 202 disposed in a metal structures 108 of a metallization layer 106(1)-106(4) in the package substrate 104 in FIG. 1 to form a void-defined section 120 for reducing metal stiffness in the metal structures 108 can be provided in any design and pattered desired. For example, FIG. 3 is a top view of an exemplary metal structure 308 that has patterned voids 302 in the shape of a honeycomb pattern (i.e., hexagonally-shaped voids) to form a void-defined section 300 in the metal structure 308 to reduce metal stiffness of the metal structure 308. Metal interconnects 306 are formed by a metal material 304 of the metal structure 308 remaining between adjacent voids 302 The metal structure 308 can serve a ground plane in a metallization layer in a package substrate of a die module package, such as a metallization layer 106(1)-106(4) in the package substrate 104 of the die module package 100 in FIG. 1 as an example. The metal structure 308 is formed from a metal material 304, such as copper. A dielectric material 310 can be disposed in the patterned voids 302. The patterned voids 302 are uniform in the metal structure 308 in this example meaning they have the same shape and orientation as shown in FIG. 3. The ratio of the area of the plurality of patterned voids 302 to the area of the metal material 304 in the metal structure 308 may be five percent (5%) or greater to achieve the desired reduction in metal stiffness of the metal structure 308.

The patterned voids 302 are also disposed in the metal structure 308 in a repeated pattern as shown FIG. 3, meaning the patterned voids 302 are oriented and placed in the metal structure 308 in repeated manner. For example, as shown in FIG. 3, the pattern of the patterned voids 302 is shown in the dashed box 309. In the example in FIG. 3, the patterned voids 302 are completely surrounded by the metal material 304 in the metal structure 308. Also in this example, the patterned voids 302 disposed in the metal structure 308 can be designed to have a combined area that is at least thirty percent (30%) of the total area of the metal structure 308. Each patterned void 302 in a row (e.g., row R₁) is offset along a center line CTR₁ between two adjacent patterned voids 302 in an adjacent row (e.g., row R₂). Also, each patterned void 302 in a column (e.g., row C₁) is offset along a center line CTR₂ between two adjacent patterned voids 302 in an adjacent column (e.g., column C₂). The patterned voids 302 each have the same first pitch P₁ in the X-axis direction. The patterned voids 302 also each have the same second pitch P₂ in the Y-axis direction. The first and second pitches P₁ and P₂ could be the same pitch or different pitches. The patterned voids 302 being the same shape and orientation and having the same pitch P₁ in the X-axis direction means that the metal structure 308 is flexible uniformly in the X-axis direction. The patterned voids 302 being the same shape and having the same pitch P₂ in the Y-axis direction means that the metal structure 308 is flexible uniformly in the Y-axis direction. If it is desired for the metal structure 308 to have the same flexibility in both the X- and Y-axis directions, the patterned voids 302 could be formed in the metal structure 308 to be of the same pitch P₁, P₂.

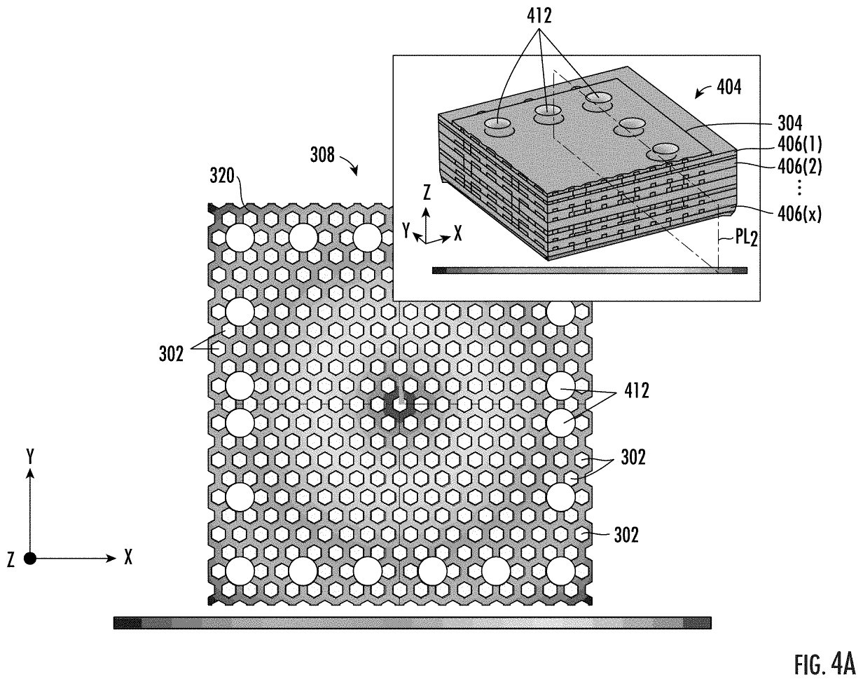

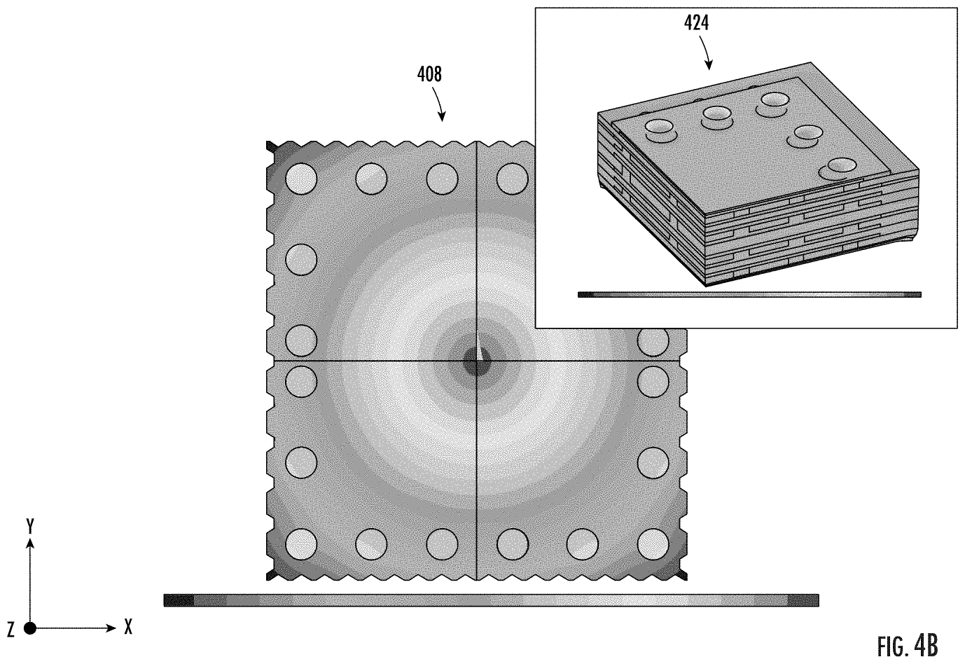

To further illustrate the exemplary effect of disposing the patterned voids 302 in the metal structure 308 in FIG. 3, FIG. 4A is provided. FIG. 4A is a diagram illustrating exemplary simulated results of the mechanical expansion of a package substrate 404 in which the metal structure 308 in FIG. 3 is provided, at a given temperature given the effect of the patterned voids 302 forming void-defined sections 320 in the metal structure 308. In the example in FIG. 4A, the package substrate 404 includes a plurality of metallization layers 406(1)-406(X) that each include metal structures 308 having a void-defined section 320 formed by voids 302 disposed between vias 412. The metal structures 308 in the multiple metallization layers 406(1)-406(X) can be aligned to be parallel to each other in a horizontal direction (e.g. in an X-axis direction) and share a common vertical plane PL₂ (in the Z- and Y-axis direction) to at least partially (i.e., fully or partially) overlap each other in the vertical direction (Z-axis direction), FIG. 4B is a diagram illustrating exemplary simulated results of the mechanical expansion of a package substrate 424 at a given temperature that includes a metal structure 408 that is full copper and like the metal structure 308 in FIG. 3, but without the inclusion of the voids 302 in void-defined sections 320. With reference to FIG. 4A, the different areas of the metal structure 308 is shown by the color variation in the metal structure 308 in the X-, Y-, and Z-axis directions. The distance of the change in color illustrates mechanical displacement. With reference to FIG. 4B, the different areas of the metal structure 408 are also shown by the color variation in the metal structure 408 in the X-, Y-, and Z-axis directions. The distance of the change in color illustrates mechanical displacement. The overall effective CTE of the metal structure 308 in FIG. 4A was found to be approximately 20% lower than the effective CTE of the metal structure 408 without voids providing void-defined sections in FIG. 4B.

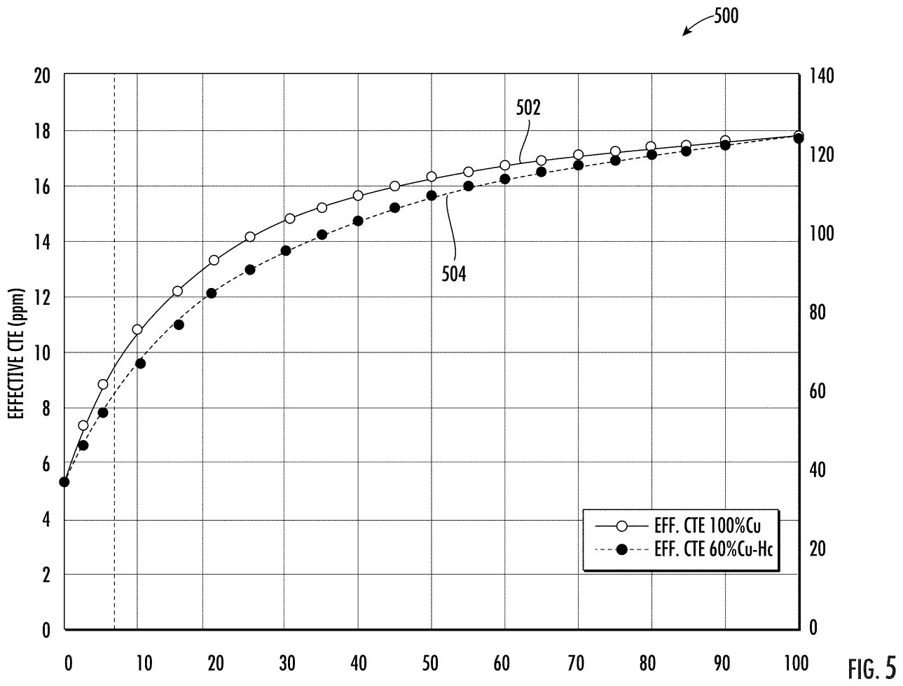

FIG. 5 is a graph 500 illustrating the effective CTE of a package substrate that can include the metal structure 308 in FIG. 3, but as a function of the volume of various metal materials to the overall volume of the package substrate. This further illustrates how the presence of the patterned voids in metal structures in the package substrate, including in ground planes, can lower the overall CTE of the ground plane. The graph 500 in FIG. 5 illustrates an effective CTE of a package substrate in the Y axis as a function of the percentage volume of copper content in a package substrate in the X axis, and the percentage volume of copper in ground planes as a function of patterned voids. As shown in FIG. 5, a first curve 502 illustrates the effective CTE of a package substrate, for a given percentage volume of copper content in a package substrate, when employing ground planes that do not include voided patterns. A second curve 504 illustrates the effective CTE of a package substrate, for a given percentage volume of copper content in a package substrate, when employing ground planes that include voided patterns where the metal material is 60% of the volume of the ground planes. As shown in FIG. 5, the effective CTE in the second curve 504 is less than the effective CTE in the first curve 502 for a given percentage volume of copper content in a package substrate.

FIG. 6 is a top view of another exemplary metal structure 608 that can be provided in a metallization layer 601 with patterned voids 602 elongated in the Y-axis direction to bias the reduction in metal stiffness of the metal structure 608 based on an imparted mechanical force. Similar to the metal structure 308 in FIG. 3, the metal structure 608 in FIG. 6 has patterned voids 602 in the shape of a honeycomb pattern (i.e., hexagonally-shaped voids) to create a void-defined area 620 in the metal structure 608 to reduce metal stiffness of the metal structure 608. Metal interconnects 606 are formed in the metal material 604 of the metal structure 608 between adjacent voids 602. The metal structure 608 can serve as a ground plane in a package substrate, such as the package substrate 104 in the die module package 100 in FIG. 1 as an example. The metal structure 608 is made from a metal material 604, such as copper. A dielectric material 612 can be disposed in the patterned voids 602. The patterned voids 602 have the same shape and orientation as shown in FIG. 6. The patterned voids 602 are also disposed in the metal structure 608 in a repeated pattern as shown FIG. 6, meaning the patterned voids 602 are oriented and placed in the metal structure in a repeated manner. For example, as shown in FIG. 6, the pattern of the patterned voids 602 is shown in the dashed box 610. Each patterned void 602 in a row (e.g., row R₁) is offset along a center line CTR₁ between two adjacent patterned voids 602 in an adjacent row (e.g., row R₂). Also, each patterned void 602 in a column (e.g., row C₁) is offset along a center line CTR₂ between two adjacent patterned voids 602 in an adjacent column (e.g., column C₂). The patterned voids 602 each have the same first pitch P₃ in the X-axis direction. The patterned voids 602 also each have the same second pitch P₄ in the Y-axis direction.

In this example, the first pitch P₃ is less than the second pitch P_{4,} because the length L₁ of the patterned voids 602 in the Y-axis direction is longer than the length L₂ in the X-axis direction. Thus, the patterned voids 602 are elongated in the Y-axis direction. This has the effect of the patterned voids 602 reducing the stiffness in the X-axis direction more than in the Y-axis direction. This may be desired to bias the direction of the reduction in stiffness in the metal structure 608. In the example in FIG. 6, the patterned voids 602 are completely surrounded by the metal material 604 in the metal structure 608. Also, in this example in FIG. 6, the patterned voids 602 disposed in the metal structure 608 can be designed to have a combined area that is at least thirty percent (30%) of the total area of the metal structure 608.

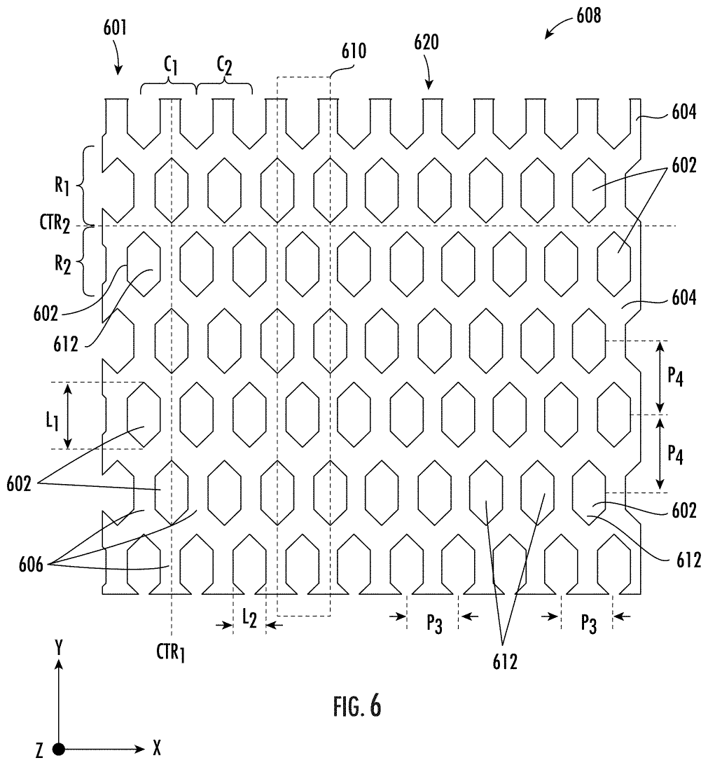

It may also be desired to provide for vias to be distributed and extend through the metal structure that has a void-defined section 720 in a subset of its patterned voids, such as the metal structure 308 in FIG. 3, to provide interconnections to the metal structure. In this regard, FIG. 7 is a top view of another exemplary metal structure 708 that can be provided in a metallization layer of a package substrate, like package substrate 104 in FIG. 1. The metal structure 708 in FIG. 7 is similar to the metal structure 308 in FIG. 3. Metal interconnects 706 are formed in the metal material 704 of the metal structure 708 between adjacent patterned voids 702. However in FIG. 7, certain patterned voids 702 formed in the metal material 704 of the metal structure 708 are not filled with the dielectric material, but rather vias 712 are disposed in these patterned voids 702 to provide interconnections to adjacent metallization layers adjacent to the metallization layer in which the metal structure 708 is disposed. This will change the overall volume of patterned voids 702 with the dielectric material 714 in the metal structure 708, which will affect the overall reduction in metal stiffness and effective CTE of the metal structure 708. However, a smaller reduction in metal stiffness may be desired. as a tradeoff for interconnection routing efficiency by the placement of the vias 712. Other elements of the metal structure 708 in FIG. 7 that are common with elements in the metal structure 308 in FIG. 3 are shown with common element numbers and labeling between FIG. 3 and FIG. 7. Also, in the example in FIG. 7, the patterned voids 702 are completely surrounded by the metal material 704 in the metal structure 708. Also, in this example, the patterned voids 702 disposed in the metal structure 708 can be designed to have a combined area that is at least thirty percent (30%) of the total area of the metal structure 708.

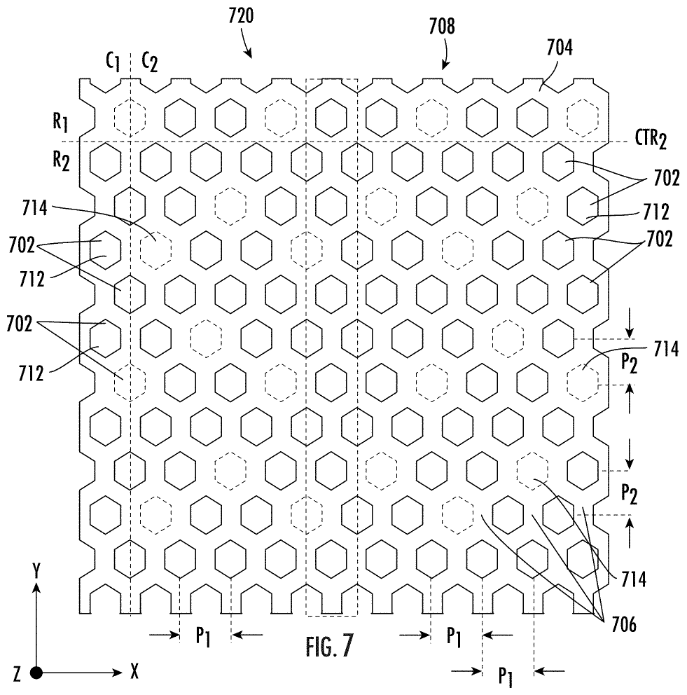

FIG. 8 is a top view of another exemplary metal structure 808 of a metal material 804 that can be provided in a metallization layer of a package substrate, such as a metallization layer 106(1)-106(4) in the package substrate 104 in FIG. 1, and includes a void-defined section 820 with patterned voids 802. Metal interconnects 806 are formed in the metal material 804 of the metal structure 808 between adjacent voids 802. The voids 802 formed in the metal structure 808 in FIG. 8 are even further elongated in the Y-axis direction than the metal structure 608 in FIG. 6 to bias the reduction in metal stiffness of the metal structure 808 based on an imparted mechanical force. The metal structure 808 in FIG. 8 has patterned voids 802 in the shape of elongated slots in the Y-axis direction to reduce metal stiffness of the metal structure 808 in the X-axis direction. The metal structure 808 can serve as a ground plane in a package substrate 104 of a die module package, such as the die module package 100 in FIG. 1 as an example. The metal structure 808 is made from a metal material 804, such as copper. A dielectric material 814 can be disposed in the patterned voids 802 to further reduce the effective CTE of the void-defined section 820 and the metal structure 808. The patterned voids 802 have the same shape and orientation. The patterned voids 802 are also disposed in the metal structure 808 in a repeated pattern as shown FIG. 8, meaning the patterned voids 802 are oriented and placed in the metal structure in repeated manner. For example, as shown in FIG. 8, the pattern of the patterned voids 802 is shown in the dashed box 810. The patterned voids 802 each have the same first pitch P₅ in the X-axis direction. The patterned voids 802 also each have the same second pitch P₆ in the Y-axis direction. In this example, the first pitch P₅ is less than the second pitch P₆, because the length L₃ of the patterned voids 802 in the Y-axis direction is longer than the length L₄ in the X-axis direction. Thus, the patterned voids 802 are elongated in the Y-axis direction. This has the effect of the patterned voids 802 reducing the stiffness in the X-axis direction more than in the Y-axis direction. This may be desired to bias the direction of the reduction in stiffness in the ground plane 800. In this example, the patterned voids 802 having the length L₃ in the Y-axis direction much greater than the length L₄ in the X-axis direction creates in essence, springs, in the metal structure 808 to provide for a flexible metal structure 808 in the X-axis direction.

Also, as shown in FIG. 8, some or all of the voids 802 can facilitate through-vias 812 to facilitate interconnections between the metal interconnects 806 in the void-defined section 820 and adjacent metallization layers. The vias 812 can also be disposed in the voids 802 in an alternating manner of either extending to an upper adjacent metallization layer in the Z-axis direction (signified by a dot inside the void 802 in FIG. 8), or extending to a lower adjacent metallization layer in the Z-axis direction (signified by a ‘X’ inside the void 802 in FIG. 8) to provide symmetry in stiffness and bending of the void-defined section 820. Also, in the example in FIG. 8, the voids 802 are completely surrounded by the metal material 804 in the metal structure 808. Also, in this example, the voids 802 disposed in the metal structure 808 can be designed to have a combined area that is at least thirty percent (30%) of the total area of the metal structure 808.

It is also possible to provide for non-patterned voids in a metal structure in a metallization layer in a package substrate to form a void-defined section in the metal structure. For example, the voids can be disposed in a metal structure that provides a ground plane in a package substrate. For example, voids can be selectively disposed in a metal structure, such as a ground plane, of a package substrate adjacent to metal lines or traces and/or other electrical components in the package substrate to provide selective mechanical stress relief to such metal lines or traces and/or other electrical components.

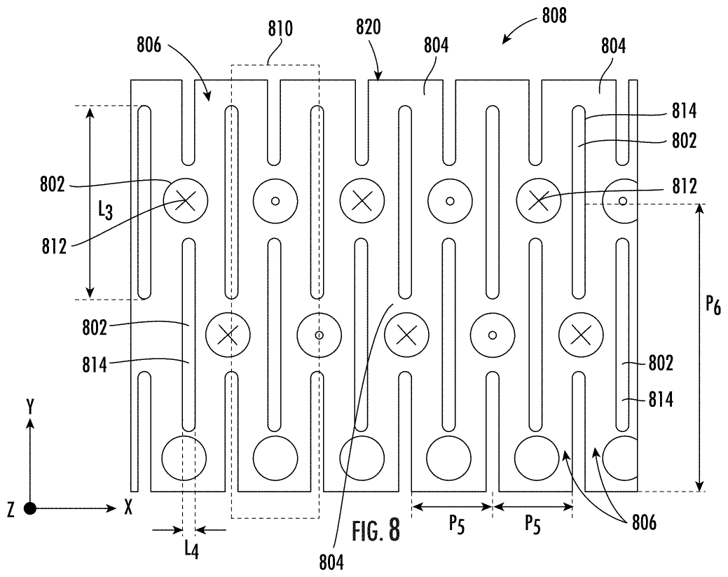

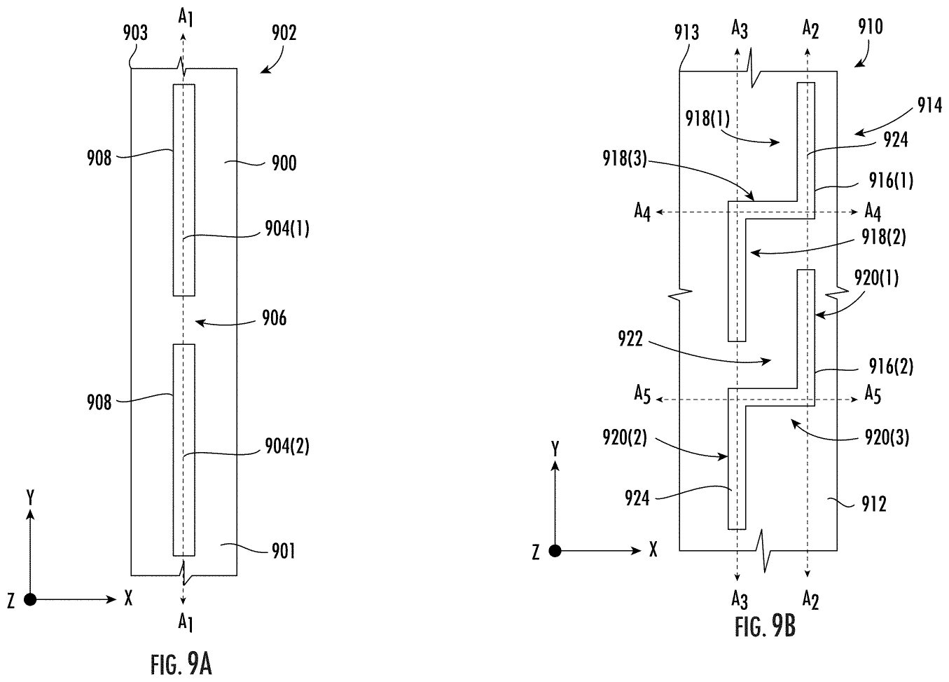

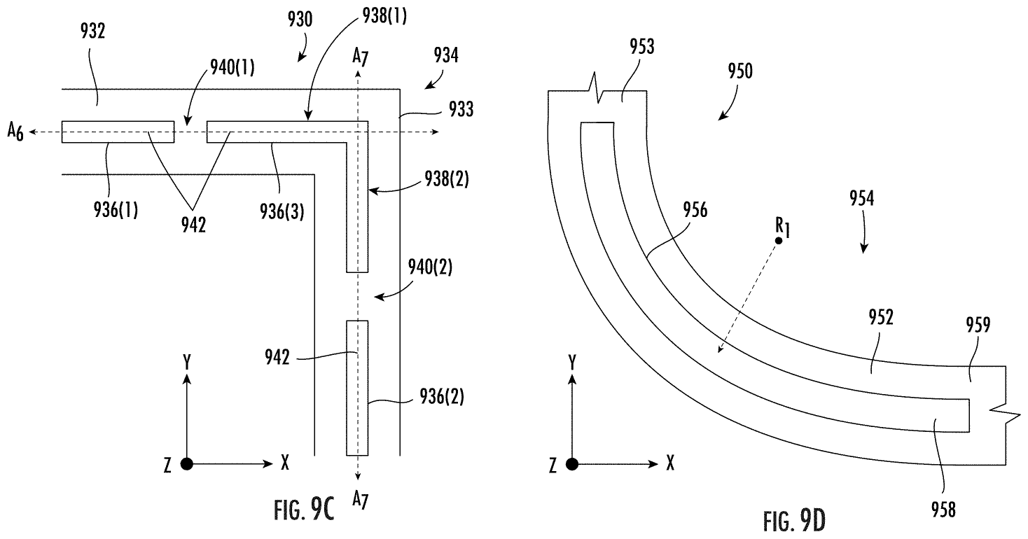

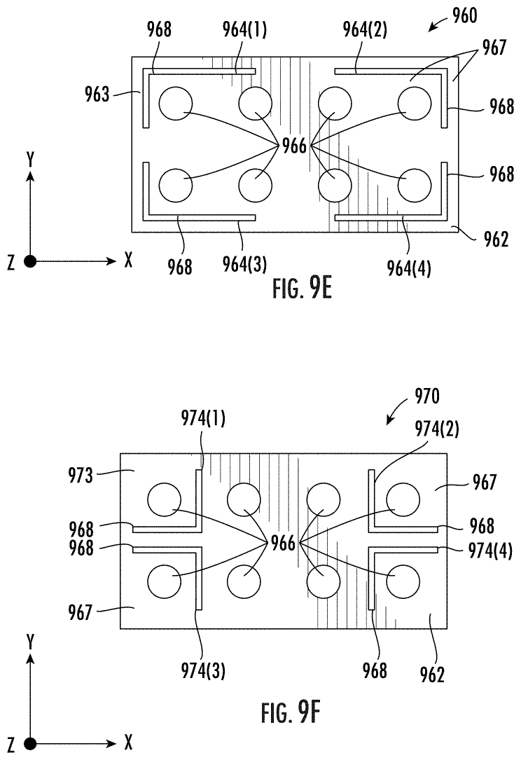

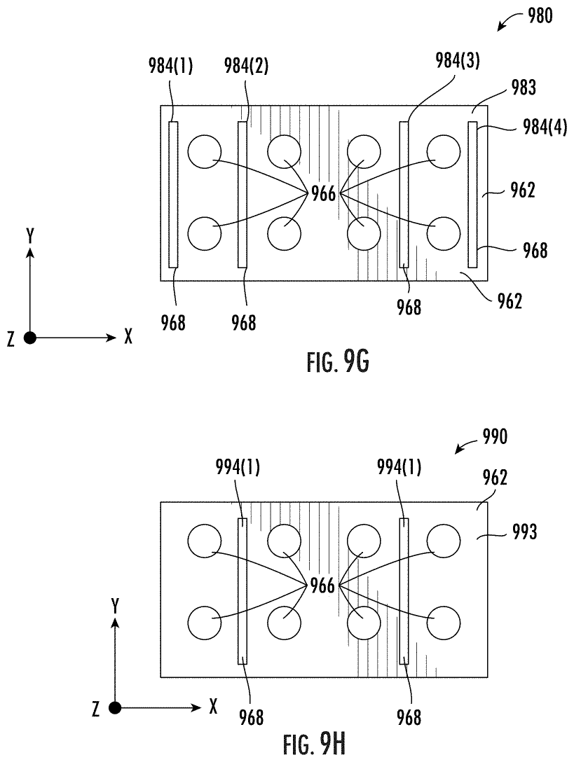

In this regard, FIGS. 9A-9H are top views of other exemplary metal structures in a metallization layer having patterned voids or cutouts selectively provided adjacent to metal traces and/or other electrical components in a package substrate to provide a void-defined section in the metal structure. The void-defined section can be coupled to vias or other interconnects in a package substrate provide selective mechanical stress relief to such interconnections and electrical components coupled to such interconnections.

FIG. 9A is a top view of a metal structure 900 having a void-defined section 903 formed by voids in the metal material 901 of the metal structure 900 that can be provided in a package substrate 902, such as the package substrate 104 in FIG. 1. A first void 904(1) is disposed in the metal structure 900. A second void 904(2) is also disposed adjacent to the first void 904(1) in the metal structure 900 such that a metal interconnect 906 is formed in the metal structure 900 between the first void 904(1) and the second void 904(2). The second void 904(2) is aligned along the same axis A₁ of the first void 904(1). A dielectric material 908 can be disposed in the first void 904(1) and/or the second void 904(2) such that the dielectric material 908 has a CTE lower than the CTE of the metal material 901 of the metal structure 900. In this manner, the stiffness of the metal structure 900 adjacent to the metal interconnect 906 is reduced, which can reduce or avoid damage to the metal interconnect 906 and metal material 901 adjacent to the voids 904(1), 904(2) in response to an imparted stress force.

FIG. 9B is a top view of a metal structure 910 having a void-defined section 913 formed by voids in the metal material 912 of the metal structure 910 that can be provided in a package substrate 914, such as the package substrate 104 in FIG. 1. A first void 916(1) is disposed in the metal structure 910. The first void 916(1) includes a first elongated void portion 918(1) aligned in its long direction with a first axis A₂ and a second elongated void portion 918(2) aligned in its long direction with a second axis A₃ parallel to the first axis A₂. A third void portion 918(3) couples the first elongated void portion 918(1) and the second elongated void portion 918(2). The third void portion 918(3) is aligned in its long direction with a third axis A₄ orthogonal to the first and second axes A₂, A₃. The second void 916(2) includes a fourth elongated portion 920(1) aligned in its long direction with the first axis A₂ and a fifth elongated void portion 920(2) aligned in its long direction with the second axis A₃. A sixth void portion 920(3) couples the fourth elongated void portion 920(1) and the fifth elongated void portion 920(2). The sixth void portion 920(3) is aligned in its long direction with a fourth axis A₅ orthogonal to the first and second axes A₂, A₃. A metal interconnect 922 is formed in the space between the respective first and fourth elongated void portions 918(1), 920(1), the respective second and fifth elongated void portions 918(2), 920(2), and the respective third and sixth void portions 918(3), 920(3). A dielectric material 924 can be disposed in the void portions 918(1)-918(3), 920(1)-920(3) such that the dielectric material 924 has a CTE lower than the CTE of the metal material 912 of the metal structure 910. In this manner, the stiffness of the metal structure 910 adjacent to the metal interconnect 922 is reduced, which can reduce or avoid damage to the metal interconnect 922 and metal material 912 adjacent to the voids 916(1), 916(2) in response to an imparted stress force.

FIG. 9C is a top view of another metal structure 930 having a void-defined section 933 formed by voids in the metal material 932 of the metal structure 930 that can be provided in a package substrate 934, such as the package substrate 104 in FIG. 1. A first void 936(1) is disposed in the metal structure 930. The first void 936(1) is aligned in its long direction with a first axis A₆. A second void 936(2) is disposed in the metal structure 930 and aligned in its long direction with a second axis A₇ orthogonal to the first axis A₆. A third void 936(3) is disposed in the metal structure 930 between the first and second voids 936(1), 936(2) and includes elongated void portions 938(1), 938(2) aligned in their long directions along the respective first and second axes A₆, A₇. In this manner, the voids 936(1)-936(3) form an L-shape in the metal structure 930 wherein two metal interconnects 940(1), 940(2) are formed between the respective voids 936(1)-936(3). A dielectric material 942 can disposed in the voids 936(1)-936(3) such that the dielectric material 942 has a CTE lower than the CTE of the metal material 932 of the metal structure 930. In this manner, the stiffness of the metal structure 930 adjacent to the metal interconnects 940(1), 940(2) is reduced, which can reduce or avoid damage to the metal interconnects 940(1), 940(2) and metal material 932 adjacent to the voids 936(1)-936(3) in response to an imparted stress force.

FIG. 9D is a top view of another metal structure 950 having a void-defined section 953 formed by voids in the metal material 952 of the metal structure 950 that can be provided in a package substrate 954, such as the package substrate 104 in FIG. 1. A curved void 956 of radius R₁ is disposed in the metal structure 950. A dielectric material 958 can disposed in the void 956 such that the dielectric material 958 has a CTE lower than the CTE of the metal material 952 of the metal structure 950. In this manner, the stiffness of the metal structure 950 adjacent to the void 956 is reduced, which can avoid damage in response to an imparted stress force. Metal interconnects 959 are formed adjacent to the void 956.

FIGS. 9E-9H are top views of other respective metal structures 960, 970, 980, 990 having respective void-defined sections 963, 973, 983, 993 formed by voids in in a metal material 962 of the metal structures 960, 970, 980, 990 that can be provided in a package substrate, such as the package substrate 104 in FIG. 1. FIG. 9E includes four voids 964(1)-964(4) that surround vias 966 to form metal interconnects 967. A dielectric material 968 can disposed in the voids 964(1)-964(4) such that the dielectric material 968 has a CTE lower than the CTE of the metal material 962 of the metal structure 960. FIG. 9F is a metal structure 970 that includes four voids 974(1)-974(4) that surround vias 966 to provide interconnects in a different arrangement than in FIG. 9E. A dielectric material 968 can disposed in the voids 974(1)-974(4) such that the dielectric material 968 has a CTE lower than the CTE of the metal material 962 of the metal structure 970. FIG. 9G is a metal structure 980 that includes four voids 984(1)-984(4) that surround vias 966 to provide interconnects in a different arrangement than in FIG. 9F. A dielectric material 968 can disposed in the voids 984(1)-984(4) such that the dielectric material 968 has a CTE lower than the CTE of the metal material 962 of the metal structure 980. FIG. 9H is yet another metal structure 990 that includes two voids 994(1), 994(2) that surround vias 966 to provide interconnects in a different arrangement than in FIG. 9G. A dielectric material 968 can disposed in the voids 994(1), 994(2) such that the dielectric material 968 has a CTE lower than the CTE of the metal material 962 of the metal structure 990.

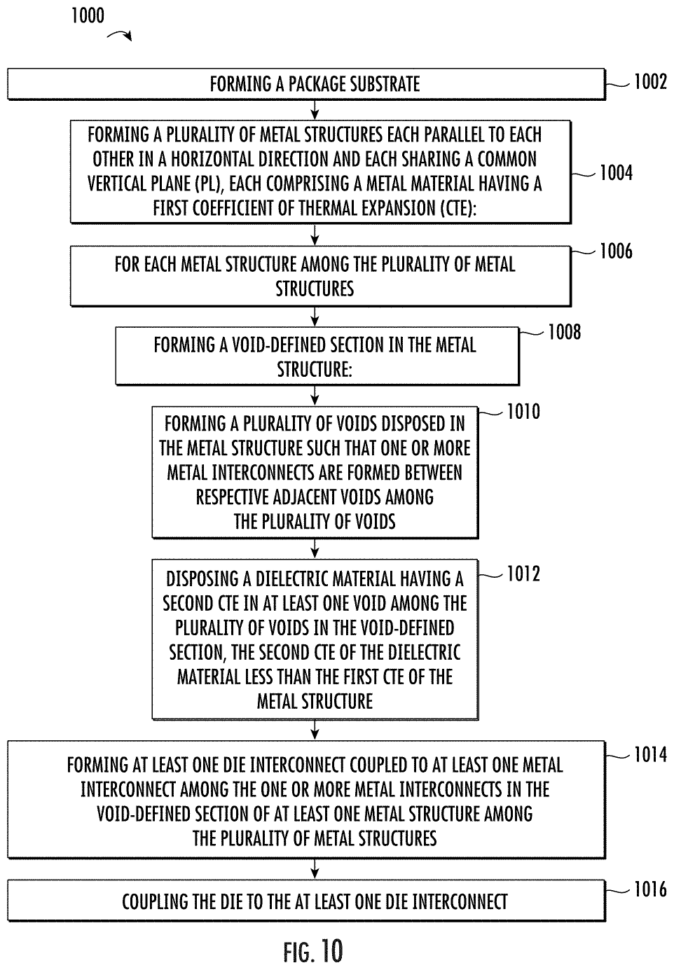

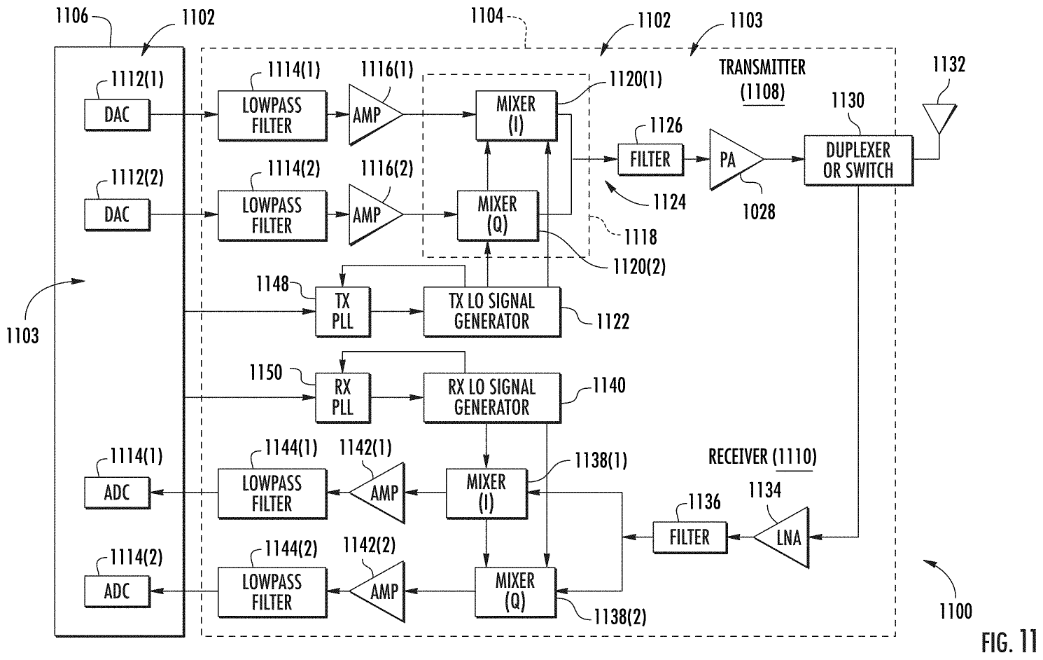

FIG. 10 is a flowchart illustrating an exemplary fabrication process 1000 of fabricating a die module package, such as the die module package 100 in FIG. 1, that includes a package substrate that includes one or more metal structures with void-defined sections formed by voids in a metal material of the metal structure(s). The void-defined sections can reduce metal stiffness of the metal structure(s) to reduce die-substrate mechanical stress between the package substrate, and the die interconnects and dies. The exemplary fabrication process 1000 will be discussed in reference to the die module package 100 in FIGS. 1 and 2. However, note that the fabrication process 1000 could also be used to fabricate the metal structures 308, 408, 608, 708, 808, 908, 910, 930, 950, 960, 970, 980, 990 in FIGS. 3, 4, and 6-9H, respectively.

In this regard, with reference to FIG. 10, a first step in the process 1000 is forming a package substrate 104 (block 1002 in FIG. 10). A next step in the process 1000 is forming a plurality of metal structures 108 in parallel with each other and sharing a common vertical plane to each partially overlapping each other in a vertical direction and each comprising a metal material 204 having a first CTE (block 1004 in FIG. 10). Then, for each metal structure 108 among the plurality of metal structures 108 (block 1006 in FIG. 10), a next step in the process is forming a void-defined section 120 in the metal structure 108 (block 1008 in FIG. 10). This process 1000 also includes, for each metal structure 108 among the plurality of metal structures 108, forming a plurality of voids 202 disposed in the metal structure 108 such that one or more metal interconnects 206 are formed between respective adjacent voids 202 among the plurality of voids 202 (block 1010 in FIG. 10). This process 1000 also includes, for each metal structure 108 among the plurality of metal structures 108, disposing a dielectric material 210 having a second CTE in at least one void 202 among the plurality of voids 202 in the void-defined section 120, the second CTE of the dielectric material 210 less than the first CTE of the metal structure 108 (block 1012 in FIG. 10). The process 1000 also includes forming at least one die interconnect 114 coupled to at least one metal interconnect 206 among the one or more metal interconnects 206 in the void-defined section 120 (block 1014 in FIG. 10). The process 1000 also includes coupling the die 102(1), 102(2) to the at least one die interconnect 114 (block 1016 in FIG. 10).

It should be understood that that the terms “top,” “above,” “bottom,” below,” where used herein, are relative terms and are not meant to limit or imply a strict orientation. A “top” referenced element does not always be oriented to be above a “bottom” referenced element with respect to ground, and vice versa. An element referenced as “top” or “bottom” may be on top or bottom relative to that example only and the particular illustrated example. An element referenced as “above” or “below” another element does not have to be with respect to ground, and vice versa. An element referenced as “above” or “below” may be on above or below and to such other referenced element, relative to that example only and the particular illustrated example.

Die module packages that include a package substrate that includes one or more metal structures with void-defined sections formed by voids in a metal material of the metal structure(s) to reduce metal stiffness of the metal structure(s), including, but not limited to, the package substrates in FIGS. 1-3 and 6-9H, and according to the exemplary fabrication process in FIG. 10, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

In this regard, FIG. 11 illustrates an exemplary wireless communications device 1100 that includes RF components formed from one or more ICs 1102, wherein any of the ICs 1102 can be included in an IC package 1103. The IC package 1103 can include a die module package(s) that includes a package substrate that includes one or more metal structures with void-defined sections formed by voids in a metal material of the metal structure(s) to reduce metal stiffness of the metal structure(s), including, but not limited to, the package substrates in FIGS. 1-3 and 6-9H, and according to the exemplary fabrication process in FIG. 10.

The wireless communications device 1100 may include or be provided in any of the above referenced devices, as examples. As shown in FIG. 11, the wireless communications device 1100 includes a transceiver 1104 and a data processor 1106. The data processor 1106 may include a memory to store data and program codes. The transceiver 1104 includes a transmitter 1108 and a receiver 1110 that support bi-directional communications. In general, the wireless communications device 1100 may include any number of transmitters 1108 and/or receivers 1110 for any number of communication systems and frequency bands. All or a portion of the transceiver 1104 may be implemented on one or more analog ICs, RF ICs (RFICs), mixed-signal ICs, etc.

The transmitter 1108 or the receiver 1110 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 1110. In the direct-conversion architecture, a signal is frequency-converted between RF and baseband in one stage. The super-heterodyne and direct-conversion architectures may use different circuit blocks and/or have different requirements. In the wireless communications device 1100 in FIG. 11, the transmitter 1108 and the receiver 1110 are implemented with the direct-conversion architecture.

In the transmit path, the data processor 1106 processes data to be transmitted and provides I and Q analog output signals to the transmitter 1108. In the exemplary wireless communications device 1100, the data processor 1106 includes digital-to-analog converters (DACs) 1112(1), 1112(2) for converting digital signals generated by the data processor 1106 into the I and Q analog output signals, e.g., I and Q output currents, for further processing.

Within the transmitter 1108, lowpass filters 1114(1), 1114(2) filter the I and Q analog output signals, respectively, to remove undesired signals caused by the prior digital-to-analog conversion. Amplifiers (AMPs) 1116(1), 1116(2) amplify the signals from the lowpass filters 1114(1), 1114(2), respectively, and provide I and Q baseband signals. An upconverter 1118 upconverts the I and Q baseband signals with I and Q transmit (TX) local oscillator (LO) signals through mixers 1120(1), 1120(2) from a TX LO signal generator 1122 to provide an upconverted signal 1124. A filter 1126 filters the upconverted signal 1124 to remove undesired signals caused by the frequency upconversion as well as noise in a receive frequency band. A power amplifier (PA) 1128 amplifies the upconverted signal 1124 from the filter 1126 to obtain the desired output power level and provides a transmit RF signal. The transmit RF signal is routed through a duplexer or switch 1130 and transmitted via an antenna 1132.

In the receive path, the antenna 1132 receives signals transmitted by base stations and provides a received RF signal, which is routed through the duplexer or switch 1130 and provided to a low noise amplifier (LNA) 1134. The duplexer or switch 1130 is designed to operate with a specific receive (RX)-to-TX duplexer frequency separation, such that RX signals are isolated from TX signals. The received RF signal is amplified by the LNA 1134 and filtered by a filter 1136 to obtain a desired RF input signal. Downconversion mixers 1138(1), 1138(2) mix the output of the filter 1136 with I and Q RX LO signals (i.e., LO_I and LO_Q) from an RX LO signal generator 1140 to generate I and Q baseband signals. The I and Q baseband signals are amplified by AMPS 1142(1), 1142(2) and further filtered by lowpass filters 1144(1), 1144(2) to obtain I and Q analog input signals, which are provided to the data processor 1106. In this example, the data processor 1106 includes analog-to-digital converters (ADCs) 1146(1), 1146(2) for converting the analog input signals into digital signals to be further processed by the data processor 1106.

In the wireless communications device 1100 of FIG. 11, the TX LO signal generator 1122 generates the I and Q TX LO signals used for frequency upconversion, while the RX LO signal generator 1140 generates the I and Q RX LO signals used for frequency downconversion. Each LO signal is a periodic signal with a particular fundamental frequency. A TX phase-locked loop (PLL) circuit 1148 receives timing information from the data processor 1106 and generates a control signal used to adjust the frequency and/or phase of the TX LO signals from the TX LO signal generator 1122. Similarly, an RX PLL circuit 1150 receives timing information from the data processor 1106 and generates a control signal used to adjust the frequency and/or phase of the RX LO signals from the RX LO signal generator 1140.

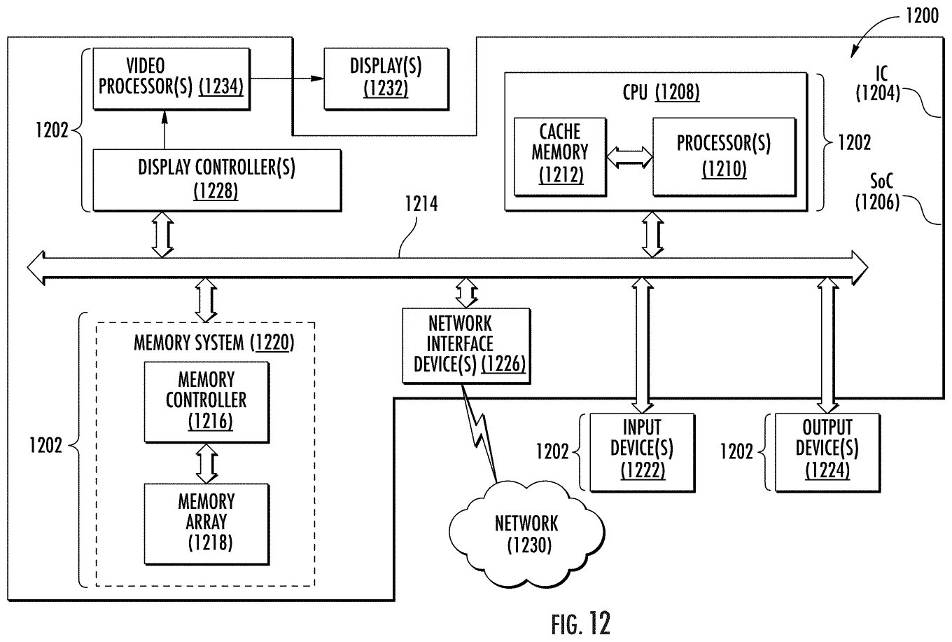

FIG. 12 illustrates an example of a wireless communication device as a processor-based system 1200 that can include a die module package(s) that includes a package substrate that includes one or more metal structures with void-defined sections formed by voids in a metal material of the metal structure(s) to reduce metal stiffness of the metal structure(s), including, but not limited to, the package substrates in FIGS. 1-3 and 6-9H, and according to the exemplary fabrication process in FIG. 10, and according to any aspects disclosed herein. In this example, the processor-based system 1200 may be formed as an IC 1204 in an IC package 1202 and as a system-on-a-chip (SoC) 1206. The processor-based system 1200 includes a central processing unit (CPU) 1208 that includes one or more processors 1210, which may also be referred to as CPU cores or processor cores. The CPU 1208 may have cache memory 1212 coupled to the CPU 1208 for rapid access to temporarily stored data. The CPU 1208 is coupled to a system bus 1214 and can intercouple master and slave devices included in the processor-based system 1200. As is well known, the CPU 1208 communicates with these other devices by exchanging address, control, and data information over the system bus 1214. For example, the CPU 1208 can communicate bus transaction requests to a memory controller 1216 as an example of a slave device. Although not illustrated in FIG. 12, multiple system buses 1214 could be provided, wherein each system bus 1214 constitutes a different fabric.

Other master and slave devices can be connected to the system bus 1214. As illustrated in FIG. 12, these devices can include a memory system 1220 that includes the memory controller 1216 and a memory array(s) 1218, one or more input devices 1222, one or more output devices 1224, one or more network interface devices 1226, and one or more display controllers 1228, as examples. Each of the memory system 1220, the one or more input devices 1222, the one or more output devices 1224, the one or more network interface devices 1226, and the one or more display controllers 1228 can be provided in the same or different die module packages 1202. The input device(s) 1222 can include any type of input device, including, but not limited to, input keys, switches, voice processors, etc. The output device(s) 1224 can include any type of output device, including, but not limited to, audio, video, other visual indicators, etc. The network interface device(s) 1226 can be any device configured to allow exchange of data to and from a network 1230. The network 1230 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1226 can be configured to support any type of communications protocol desired.

The CPU 1208 may also be configured to access the display controller(s) 1228 over the system bus 1214 to control information sent to one or more displays 1232. The display controller(s) 1228 sends information to the display(s) 1232 to be displayed via one or more video processors 1234, which process the information to be displayed into a format suitable for the displays) 1232. The display controller(s) 1228 and video processor(s) 1234 can be included as ICs in the same or different die module packages 1202, and in the same or different die module package 1202 containing the CPU 1208 as an example. The display(s) 1232 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. A die module package, comprising:

a package substrate, comprising:
a plurality of metal structures parallel to each other in a horizontal direction and sharing a common vertical plane,
each metal structure among the plurality of metal structures comprising:
   a metal material having a first coefficient of thermal expansion (CTE);
   a void-defined section comprising a plurality of voids disposed in the metal structure;
   one or more metal interconnects each formed by the metal material in the metal structure disposed between adjacent voids among the plurality of voids; and
   a dielectric material having a second CTE disposed in at least one void among the plurality of voids in the void-defined section, the second CTE of the dielectric material less than the first CTE of the metal material;
a die disposed adjacent to the package substrate; and
at least one die interconnect each coupled to the die and each coupled to a metal interconnect among the one or more metal interconnects in the void-defined section of at least one metal structure among the plurality of metal structures.
   2. The die module package of clause 1, wherein at least a portion of an area of the die is oriented to the package substrate to at least partially overlap a void-defined section in the package substrate in a vertical plane.
   3. The die module package of any of clauses 1-2, wherein:
the package substrate comprises a plurality of metallization layers parallel to each other; and
each metal structure among the plurality of metal structures is disposed in a different metallization layer among the plurality of metallization layers.
   4. The die module package of any of clauses 1-3, wherein:
a first metal structure among the plurality of metal structures is disposed in a first metallization layer among the plurality of metallization layers;
a second metal structure among the plurality of metal structures is disposed in a second metallization layer among the plurality of metallization layers different from the first metallization layer; and
further comprising:
   a vertical interconnect access (via) disposed through a respective void among the plurality of voids in the void-defined section of the first metal structure;
   each via of the at least one via coupled to a metal interconnect among the plurality of metal interconnects in a void-defined section of the second metal structure.
      5. The die module package of any of clauses 1-4, wherein the plurality of voids disposed in the metal structure are each completely surrounded by and coupled to the metal material in the metal structure.
      6. The die module package of any of clauses 1-5, wherein each metal structure of the plurality of metal structures comprises a ground plane.
      7. The die module package of any of clauses 1-6, wherein the plurality of voids in each metal structure has an area that is at least thirty percent (30%) of an area of the metal structure.
      8. The die module package of any of clauses 1-7, Wherein the plurality of voids form a perimeter of the void-defined section in the metal structure.
      9. The die module package of clause 8, wherein the plurality of voids have a first area that at least eight five percent (85%) of a second area of the perimeter.
      10. The die module package of any of clauses 1-9, wherein the void-defined section of the metal structure has a Young's modulus between 100 MegaPascal (MPa) and 50 GigaPascal (GPa).
      11. The die module package of any of clauses 1-10, wherein the first CTE of the metal material of the metal structure is between 13 parts per million (ppm) per Kelvin (K) (pp/K) and 24 ppm/K.
      12. The die module package of clause 11, wherein the second CTE of the dielectric material is between 4 ppm/K and 18 ppm/K.
      13. The die module package of any of clauses 1-12, wherein the plurality of voids in at least one metal structure among the plurality of metal structures are formed in a repeated pattern in the metal structure.
      14. The die module package of any of clauses 1-13, wherein each of the plurality of voids in at least one metal structure among the plurality of metal structures has a same first pitch in a first direction of a first axis and has a same second pitch in a second direction of a second axis orthogonal to the first axis.
      15. The die module package of any of clauses 1-14, wherein each of the plurality of voids in at least one metal structure among the plurality of metal structures comprises an elongated void having a first length in a first direction of a first axis and a second length in a second direction in a second axis orthogonal to the first axis, wherein the second length is equal to the first length.
      16. The die module package of any of clauses 1-15, Wherein each of the plurality of voids in at least one metal structure among the plurality of metal structures comprises an elongated void having a first length in a first direction of a first axis and a second length in a second direction in a second axis orthogonal to the first axis, wherein the second length is less than the first length.
      17. The die module package of any of clauses 1-16, wherein at least one metal structure among the plurality of metal structures is uniformly deformable along at least two orthogonal axes.
      18. The die module package of clause 17, wherein the plurality of voids in at least one metal structure among the plurality of metal structures have the same pitch.
      19. The die module package of any of clauses 1-18, wherein a subset of voids among the plurality of voids in at least one metal structure among the plurality of metal structures are elongated along the same axis.
      20. The die module package of any of clauses 1-19, wherein the void-defined section in at least one metal structure among the plurality of metal structures is a square-shaped void-defined section comprising a plurality of straight voids disposed along a square-shaped perimeter forming a perimeter of the void-defined section.
      21. The die module package of any of clauses 1-20, wherein the void-defined section in at least one metal structure among the plurality of metal structures is a circular-shaped void-defined section comprising a plurality of convex voids disposed along a circular-shaped perimeter forming a perimeter of the void-defined section.
      22. The die module package of any of clauses 1-21, wherein for at least one metal structure among the plurality of metal structures:
a first void among the plurality of voids comprises:
   a first elongated void portion aligned with a first axis;
   a second elongated void portion aligned with a second axis parallel to the first axis; and
   a third void portion coupling the first elongated void portion and the second elongated void portion; and
a second void among the plurality of voids comprises:
   a fourth elongated void portion aligned with the first axis and separated from the first elongated void portion by a first metal void portion in the at least one metal structure;
   a fifth elongated void portion aligned with the second axis and separated from the first elongated void portion by a second metal void portion in the at least one metal structure; and
   a sixth void portion coupling the fourth elongated void portion and the fifth elongated void portion separated by a third metal void portion in the at least one metal structure;
   the first, second, and third metal void portions coupled together forming the metal interconnect.
      23. The die module package of any of clauses 1-22 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
      24. A method of fabricating a die module package, comprising:
forming a package substrate, comprising:
   forming a plurality of metal structures parallel to each other in a horizontal direction and sharing a common vertical plane, each metal structure among the plurality of metal structures comprising:
      a metal material having a first coefficient of thermal expansion (CTE);
      a void-defined section comprising a plurality of voids disposed in the metal structure;
      one or more metal interconnects each formed by the metal material in the metal structure disposed between adjacent voids among the plurality of voids; and
      a dielectric material having a second CTE disposed in at least one void among the plurality of voids in the void-defined section, the second CTE of the dielectric material less than the first CTE of the metal material.
forming at least one die interconnect coupled to at least one metal interconnect among the one or more metal interconnects in the void-defined section of at least one metal structure among the plurality of metal structures; and
coupling a die to the at least one die interconnect.
   25. The method of clause 24, wherein coupling the die to the at least one die interconnect further comprises disposing at least a portion of an area of the die oriented to the package substrate to at least partially overlap a void-defined section in at least one metal structure among the plurality of metal structures in the package substrate in a vertical plane.
   26. The method of any of clauses 24-25, further comprising:
disposing at least one vertical interconnect access (via) each through a respective void among the plurality of voids in the void-defined section of a first metal structure among the plurality of metal structures; and
coupling each via of the at least one via to a metal interconnect among the plurality of metal interconnects in a second void-defined section of a metal structure. among the plurality of metal structures
   27. The method of any of clauses 24-26, wherein forming the plurality of metal structures further comprises forming each metal structure among the plurality of metal structures in a different metallization layer among a plurality of metallization layers that are parallel to each other in the package substrate.
   28. The method of any of clauses 24-27, wherein forming the plurality of voids in the metal structure further comprises forming the plurality of voids in the metal structure such that the plurality of voids are each completely surrounded by and coupled to the metal material in the metal structure.
   29. The method of any of clauses 24-28, wherein forming the plurality of voids in the metal structure further comprises forming the plurality of voids in each metal structure to consume an area in the metal structure of least thirty percent (30%) of an area of the metal structure.
   30. The method of any of clauses 24-29, wherein the void-defined section of the metal structure has a Young's modulus between 100 MegaPascal (MPa) and 50 GigaPascal (GPa).
   31. The method of any of clauses 24-30, wherein the first CTE of the metal material is between 13 parts per million (ppm) per Kelvin (K) (ppm/K) and 24 ppm/K.
   32. The method of any of clauses 24-31, wherein the second CTE of the dielectric material is between 4 ppm/K and 18 ppm/K.

What is claimed is:

1. A die module package, comprising:
a package substrate, comprising:
a plurality of metal structures parallel to each other in a horizontal direction and sharing a common vertical plane,
each metal structure among the plurality of metal structures comprising:
a metal material having a first coefficient of thermal expansion (CTE);
a void-defined section comprising a plurality of voids disposed in the metal structure;
one or more metal interconnects each formed by the metal material in the metal structure disposed between adjacent voids among the plurality of voids; and
a dielectric material having a second CTE disposed in at least one void among the plurality of voids in the void-defined section, the second CTE of the dielectric material less than the first CTE of the metal material;
a die disposed adjacent to the package substrate; and
at least one die interconnect each coupled to the die and each coupled to a metal interconnect among the one or more metal interconnects in the void-defined section of at least one metal structure among the plurality of metal structures.

2. The die module package of claim 1, wherein at least a portion of an area of the die is oriented to the package substrate to at least partially overlap a void-defined section in the package substrate in a vertical plane.

3. The die module package of claim 1, wherein:
the package substrate comprises a plurality of metallization layers parallel to each other; and
each metal structure among the plurality of metal structures is disposed in a different metallization layer among the plurality of metallization layers.

4. The die module package of claim 1, wherein:
a first metal structure among the plurality of metal structures is disposed in a first metallization layer among the plurality of metallization layers;
a second metal structure among the plurality of metal structures is disposed in a second metallization layer among the plurality of metallization layers different from the first metallization layer; and
further comprising:
a vertical interconnect access (via) disposed through a respective void among the plurality of voids in the void-defined section of the first metal structure;
each via of the at least one via coupled to a metal interconnect among the plurality of metal interconnects in a void-defined section of the second metal structure.

5. The die module package of claim 1, wherein the plurality of voids disposed in the metal structure are each completely surrounded by and coupled to the metal material in the metal structure.

6. The die module package of claim 1, wherein each metal structure of the plurality of metal structures comprises a ground plane.

7. The die module package of claim 1, wherein the plurality of voids in each metal structure has an area that is at least thirty percent (30%) of an area of the metal structure.

8. The die module package of claim 1, wherein the plurality of voids form a perimeter of the void-defined section in the metal structure.

9. The die module package of claim 8, wherein the plurality of voids have a first area that at least eight five percent (85%) of a second area of the perimeter.

10. The die module package of claim 1, wherein the void-defined section of the metal structure has a Young's modulus between 100 MegaPascal (MPa) and 50 GigaPascal (GPa).

11. The die module package of claim 1, wherein the first CTE of the metal material of the metal structure is between 13 parts per million (ppm) per Kelvin (K) (ppm/K) and 24 ppm/K.

12. The die module package of claim 11, wherein the second CTE of the dielectric material is between 4 ppm/K and 18 ppm/K.

13. The die module package of claim 1, wherein the plurality of voids in at least one metal structure among the plurality of metal structures are formed in a repeated pattern in the metal structure.

14. The die module package of claim 1, wherein each of the plurality of voids in at least one metal structure among the plurality of metal structures has a same first pitch in a first direction of a first axis and has a same second pitch in a second direction of a second axis orthogonal to the first axis.

15. The die module package of claim 1, wherein each of the plurality of voids in at least one metal structure among the plurality of metal structures comprises an elongated void having a first length in a first direction of a first axis and a second length in a second direction in a second axis orthogonal to the first axis, wherein the second length is equal to the first length.

16. The die module package of claim 1, wherein each of the plurality of voids in at least one metal structure among the plurality of metal structures comprises an elongated void having a first length in a first direction of a first axis and a second length in a second direction in a second axis orthogonal to the first axis, wherein the second length is less than the first length.

17. The die module package of claim 1, wherein at least one metal structure among the plurality of metal structures is uniformly deformable along at least two orthogonal axes.

18. The die module package of claim 17, wherein the plurality of voids in at least one metal structure among the plurality of metal structures have the same pitch.

19. The die module package of claim 1, wherein a subset of voids among the plurality of voids in at least one metal structure among the plurality of metal structures are elongated along the same axis.

20. The die module package of claim 1, wherein the void-defined section in at least one metal structure among the plurality of metal structures is a square-shaped void-defined section comprising a plurality of straight voids disposed along a square-shaped perimeter forming a perimeter of the void-defined section.

21. The die module package of claim 1, wherein the void-defined section in at least one metal structure among the plurality of metal structures is a circular-shaped void-defined section comprising a plurality of convex voids disposed along a circular-shaped perimeter forming a perimeter of the void-defined section.

22. The die module package of claim 1, wherein for at least one metal structure among the plurality of metal structures:
a first void among the plurality of voids comprises:
a first elongated void portion aligned with a first axis;
a second elongated void portion aligned with a second axis parallel to the first axis; and
a third void portion coupling the first elongated void portion and the second elongated void portion; and
a second void among the plurality of voids comprises:
a fourth elongated void portion aligned with the first axis and separated from the first elongated void portion by a first metal void portion in the at least one metal structure;
a fifth elongated void portion aligned with the second axis and separated from the first elongated void portion by a second metal void portion in the at least one metal structure; and
a sixth void portion coupling the fourth elongated void portion and the fifth elongated void portion separated by a third metal void portion in the at least one metal structure;
the first, second, and third metal void portions coupled together forming the metal interconnect.

23. The die module package of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a pliable; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

24. A method of fabricating a die module package, comprising:
forming a package substrate, comprising:
forming a plurality of metal structures parallel to each other in a horizontal direction and sharing a common vertical plane, each metal structure among the plurality of metal structures comprising:
a metal material having a first coefficient of thermal expansion (CTE);
a void-defined section comprising a plurality of voids disposed in the metal structure;
one or more metal interconnects each formed by the metal material in the metal structure disposed between adjacent voids among the plurality of voids; and
a dielectric material having a second CTE disposed in at least one void among the plurality of voids in the void-defined section, the second CTE of the dielectric material less than the first CTE of the metal material;
forming at least one die interconnect coupled to at least one metal interconnect among the one or more metal interconnects in the void-defined section of at least one metal structure among the plurality of metal structures; and
coupling a die to the at least one die interconnect.

25. The method of claim 24, wherein coupling the die to the at least one die interconnect further comprises disposing at least a portion of an area of the die oriented to the package substrate to at least partially overlap a void-defined section in at least one metal structure among the plurality of metal structures in the package substrate in a vertical plane.

26. The method of claim 24, further comprising:
disposing at least one vertical interconnect access (via) each through a respective void among the plurality of voids in the void-defined section of a first metal structure among the plurality of metal structures; and
coupling each via of the at least one via to a metal interconnect among the plurality of metal interconnects in a second void-defined section of a metal structure among the plurality of metal structures.

27. The method of claim 24, wherein forming the plurality of metal structures further comprises forming each metal structure among the plurality of metal structures in a different metallization layer among a plurality of metallization layers that are parallel to each other in the package substrate.

28. The method of claim 24, wherein forming the plurality of voids in the metal structure further comprises forming the plurality of voids in the metal structure such that the plurality of voids are each completely surrounded by and coupled to the metal material in the metal structure.

29. The method of claim 24, wherein forming the plurality of voids in the metal structure further comprises forming the plurality of voids in each metal structure to consume an area in the metal structure of least thirty percent (30%) of an area of the metal structure.

30. The method of claim 24, wherein the void-defined section of the metal structure has a Young's modulus between 100 MegaPascal (MPa) and 50 GigaPascal (GPa).

31. The method of claim 24, wherein the first CTE of the metal material is between 13 parts per million (ppm) per Kelvin (K) (ppm/K) and 24 ppm/K.

32. The method of claim 24, wherein the second CTE of the dielectric material is between 4 ppm/K and 18 ppm/K.
